(19) United States
(12) Patent Application Publication
(10) Pub. No.: US 2014/0272184 A1
(43) Pub. Date: Sep. 18, 2014

(54) METHODS FOR MAINTAINING CLEAN ETCH RATE AND REDUCING PARTICULATE CONTAMINATION WITH PECVD OF AMORPHOUS SILICON FILIMS

(71) Applicant: APPLIED MATERIALS, INC., Santa Clara, CA (US)

(72) Inventors: Subbalakshmi SREEKALA, Milpitas, CA (US); Xinhai HAN, Fremont, CA (US); Nagarajan RAJAGOPALAN, Santa Clara, CA (US); Bok Hoen KIM, San Jose, CA (US); Yoichi SUZUKI, Chiba-Ken (JP); Tsutomu KIYOHARA, Santa Clara, CA (US)

(73) Assignee: APPLIED MATERIALS, INC., Santa Clara, CA (US)

(21) Appl. No.: 14/179,019

(22) Filed: Feb. 12, 2014

Related U.S. Application Data
(60) Provisional application No. 61/780,427, filed on Mar. 13, 2013.

(51) Int. Cl. C23C 16/44

(52) U.S. Cl. CPC C23C 16/4404
USPC 427/534

(57) ABSTRACT

Methods for maintaining clean etch rate and reducing particulate contamination with PECVD of amorphous silicon films are provided. The method comprises cleaning a processing chamber with a plasma comprising a cleaning gas, exposing at least a portion of the interior surfaces and components of the processing chamber to an oxidation gas and a nitration gas in the presence of a plasma and depositing a bi-layer seasoning layer on the interior surfaces and components of the processing chamber.

### CROSS-REFERENCE TO RELATED APPLICATIONS

This application claims benefit of U.S. Provisional Patent Application Ser. No. 61/780,427, filed Mar. 13, 2013, which is herein incorporated by reference in its entirety.

### BACKGROUND OF THE INVENTION

1. Field of the Invention

Embodiments of the present invention generally relate to the fabrication of integrated circuits. More particularly, the embodiments described herein provide cleaning techniques for a plasma chamber utilized in the manufacture of integrated circuits.

2. Description of the Related Art

One of the primary steps in the fabrication of modern semiconductor devices is the formation of a thin film on a semiconductor substrate by chemical reaction of gases. Such a deposition process is referred to as chemical vapor deposition or CVD. Conventional thermal CVD processes supply reactive gases to the substrate surface where heat-induced chemical reactions take place to produce a desired film. The high temperatures at which some thermal CVD processes operate can damage device structures having metal layers previously formed thereon.

Processes which have been developed to deposit insulation films over metal layers at relatively low temperatures include plasma-enhanced CVD (PECVD) techniques. Plasma-enhanced CVD techniques promote excitation and/or disassociation of the reactant gases by the application of radio frequency (RF) energy to a reaction zone near the substrate surface, thereby creating a plasma of highly reactive species. The high reactivity of the released species reduces the energy required for a chemical reaction to take place, and thus lowers the required temperature for such PECVD processes.

The surface upon which a CVD layer is deposited may contain sorbable contaminants such as fluorine deposits from chamber cleaning and dopants from other processes. The presence of fluorine or other sorbable contaminants, for example, boron, may affect the absorption of precursors and slow or inhibit the deposition rate of the CVD layer. Fluorine in the chamber can also form particles when contacted by the reactive gases used to make a PECVD oxide layer.

Particle contamination within the chamber is typically controlled by periodically cleaning the chamber using cleaning gases, typically fluorinated compounds, which are excited to inductively or capacitively coupled plasmas. Cleaning gases are selected based on their ability to bind the precursor gases and the deposition material which has formed on the chamber components in order to form stable volatile products which can be exhausted from the chamber, thereby cleaning the process environment.

Once the chamber has been sufficiently cleaned of the process gases and the cleaning by-products have been exhausted out of the chamber, a seasoning process is performed to deposit a film onto components of the chamber forming the processing region to seal remaining contaminants therein and reduce the contamination level during processing. This process is typically carried out by depositing a season film to coat the interior surfaces forming the processing region in accordance with the subsequent deposition process recipe.

While chamber cleaning and depositing a season film have been successful in reducing most contaminants in a plasma reactor, sorbable contaminants such as fluorine and boron have still been measured above desired levels. Therefore, there exists a need for a method for further reducing sorbable contaminants within a plasma reactor.

### SUMMARY OF THE INVENTION

Embodiments of the present invention generally relate to the fabrication of integrated circuits. More particularly, the embodiments described herein provide cleaning techniques for a plasma chamber utilized in the manufacture of integrated circuits. In one embodiment, a method for reducing sorbable contaminants in a substrate processing chamber prior to substrate processing is provided. The method comprises cleaning a processing chamber with a plasma comprising a cleaning gas, exposing at least a portion of the interior surfaces and components of the processing chamber to an oxidation gas and a nitration gas in the presence of a plasma and depositing a bi-layer seasoning layer on the interior surfaces and components of the processing chamber.

In another embodiment, a method for reducing sorbable contaminants in a processing chamber is provided. The method comprises cleaning a processing chamber having a substrate support and a showerhead disposed therein with a plasma comprising an NF₃ cleaning gas, wherein the plasma is formed by a remote plasma source, exposing at least a portion of the interior surfaces of the processing chamber to an oxidation gas and a nitration gas in the presence of a plasma and depositing a bi-layer seasoning layer on the interior surfaces of the processing chamber. The bi-layer seasoning layer comprises a silicon oxide layer formed on the interior surfaces of the processing chamber and a silicon oxynitride layer formed on the silicon oxide layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a perspective view of one embodiment of a vacuum processing system according to embodiments described herein;

FIG. 2 is a cross-sectional view of one embodiment of a processing chamber according to embodiments described herein;

FIG. 3 is a process flow diagram illustrating one embodiment of a method for cleaning a chamber according to embodiments described herein;

FIG. 4 is a graph illustrating the clean etch rate reduction for various processes according to embodiments described herein; and

FIG. 5 is a graph illustrating particle adders for single layer seasoning layers and seasoning bi-layers formed according to embodiments described herein.

To facilitate understanding, identical reference numerals have been used, where possible, to designate identical elements that are common to the figures. It is contemplated that elements disclosed in one embodiment may be beneficially used on other embodiments without specific recitation.

### DETAILED DESCRIPTION

Embodiments of the present invention generally relate to the fabrication of integrated circuits. More particularly, the embodiments described herein provide cleaning techniques for a plasma chamber utilized in the manufacture of integrated circuits. During the amorphous silicon deposition by PECVD for 3D memory applications, the processing chamber is typically seasoned in order to reduce particle contaminants and improve film properties. Amorphous silicon (a-Si) films, both doped and intrinsic are rough and have surface defects. Doped a-Si films are often doped using diborane (B₂H₆). Under plasma conditions, diborane often breaks into boron and hydrogen. In the case of boron doped a-Si, at temperatures above 400 degrees Celsius, boron dopant atoms react with the materials (e.g., aluminum) of the processing chamber walls and components in addition to other precursors and form compounds or aggregates at weak energy centers like grain boundaries. During the chamber clean, fluorine radicals are used to remove the dopant atoms but these fluorine atoms are often insufficient resulting in under cleaning of the chamber.

Certain embodiments of the invention include at least one of the following: (1) The high temperature (greater than 500 degrees Celsius) clean etch rate of a PECVD chamber deteriorates from medium and high deposition rate doped a-Si processes with a boron level of greater than 1×10²⁰ atoms/cm³. A combined oxidation and nitration treatment for the chamber walls helps to recover the chamber clean etch rate as the boron dopants react with oxygen and nitrogen atoms to form by-products which are easily removed from the interior surfaces of the chamber including the chamber components. (2) Silicon rich oxynitride and silicon nitride seasoning layers act as a barrier for boron diffusion to the interior surfaces of the chamber. Combining the chamber oxidation and nitration treatment with either seasoning layer will effectively decrease the clean etch rate degradation and improve overall film quality. (3) High compressive oxide seasoning helps to achieve better properties for boron doped a-Si films with good particle performance. Combining the nitration/oxidation treatment followed by deposition of a bi-layer comprising a high compressive oxide season with either a silicon rich oxynitride or silicon nitride seasoning results in good film properties and increases the number of wafers processed between chamber cleans. In addition this bi-layer seasoning combined with the nitration/oxidation treatment helps improve the surface roughness of a-Si and decrease surface defects. (4) Nitrous oxide (N₂O) by itself with high RF power or Nitrogen (N₂), Helium (He), and Argon (Ar) with Ar flow less than 5% with low power RF plasma in between and/or after the film deposition has also been found to decrease surface roughness and surface defects of a-Si films, both doped and intrinsic. Combining this treatment with the above two conditions (2 and 3) helps to decrease the roughness and reduce defects of a-Si films.

In certain embodiments, the flow rates described herein are based on a chamber having an interior volume of 30 liters.

FIG. 1 is a perspective view of one embodiment of a vacuum processing system that is suitable for practicing embodiments described herein and FIG. 2 is a cross-sectional schematic view of a chemical vapor deposition (CVD) chamber 106 that is suitable for practicing embodiments described herein. One example of such a chamber is a PRODUCER® dual chamber or a DxZ® chamber, used in a P-5000 mainframe or a CENTURA® platform, suitable for 200 mm, 300 mm, or larger size substrates, all of which are available from Applied Materials, Inc., of Santa Clara, Calif. Additionally, deposition systems available from other manufacturers may also benefit from embodiments described herein.

In FIG. 1, the system 100 is a self-contained system supported on a main frame structure 101 where wafer cassettes are supported and wafers are loaded into and unloaded from a loadlock chamber 112, a transfer chamber 104 housing a wafer handler, a series of tandem process chambers 106 mounted on the transfer chamber 104 and a back end 108 which houses the support utilities needed for operation of the system 100, such as a gas panel, power distribution panel and power generators. The system can be adapted to accommodate various processes and supporting chamber hardware such as CVD, PVD and etch. The embodiment described below will be directed to a system employing a CVD process, such as plasma enhanced CVD processes, to deposit a material, for example, a boron doped amorphous silicon material.

FIG. 2 shows a schematic cross-sectional view of the chamber 106 defining two processing regions 218, 220. Chamber body 202 includes chamber sidewall 212, chamber interior wall 214 and chamber bottom wall 216 which define the two processing regions 218, 220. The bottom wall 216 in each processing region 218, 220 defines at least two passages 222, 224 through which a stem 226 of a heater pedestal 228 and a rod 230 of a wafer lift pin assembly are disposed, respectively. The chamber body 202 defines a plurality of vertical gas passages for each reactant gas and cleaning gas suitable for the selected process to be delivered in the chamber through the gas distribution system. Gas inlet connections 241 are disposed at the bottom of the chamber 106 to connect the gas passages formed in the chamber wall to the gas inlet lines 239.

The chamber 106 also includes a gas distribution system 208, typically referred to as a “showerhead”, for delivering gases into the processing regions 218, 220 through a gas inlet passage 240 into a shower head assembly 242 comprised of an annular base plate 248 having a blocker plate 244 disposed intermediate a face plate 246. An RF feedthrough provides a bias potential to the showerhead assembly to facilitate generation of a plasma between the face plate 246 of the showerhead assembly and the heater pedestal 228. A cooling channel 252 is formed in the base plate 248 of each gas distribution system 208 to cool the plate during operation. An inlet 255 delivers a coolant fluid, such as water or the like, into the channels 252 which are connected to each other by coolant line 257. The cooling fluid exits the channel through a coolant outlet 260. Alternatively, the cooling fluid is circulated through the manifold. A plurality of vertical gas passages are also included in the shower head assembly 242 for each reactant gas, carrier gas, and/or cleaning gas to be delivered into the chamber through the gas distribution system 208.

A heater pedestal 228 is movably disposed in each processing region 218, 220 by a stem 226 which is connected to a lift motor 203. The stem 226 moves upwardly and downwardly in the chamber to move the heater pedestal 228 to position a substrate (not shown) thereon or remove a substrate there from for processing. A wafer positioning assembly includes a plurality of support pins 251 which move vertically with respect to the heater pedestal 228 and are received in bores 253 disposed vertically through the pedestal. Each pin 251 includes a cylindrical shaft 259 terminating in a lower spherical portion 261 and an upper truncated conical head 263 formed as an outward extension of the shaft. The bores 253 in the heater pedestal 228 include an upper, countersunk portion sized to receive the conical head 263 therein such that when the pin 251 is fully received into the heater pedestal 228, the head does not extend above the surface of the heater pedestal.

Gas flow controllers are typically used to control and regulate the flow rates of different process gases into the process chamber 106 through gas distribution system 208. Other flow control components may include a liquid flow injection valve and liquid flow controller (not shown) if liquid precursors are used. A substrate support is heated, such as by a heater having one or more resistive elements, and is mounted on the stem 226, so that the substrate support and the substrate can be controllably moved by a lift motor 203 between a lower loading/off-loading position and an upper processing position adjacent to the gas distribution system 208.

The chamber sidewall 212 and the chamber interior wall 214 define two cylindrical annular processing regions 218, 220. A circumferential pumping channel 225 is formed in the chamber walls for exhausting gases from the processing regions 218, 220 and controlling the pressure within each region 218, 220. A chamber liner or insert 227, preferably made of ceramic or the like, is disposed in each processing region 218, 220 to define the lateral boundary of each processing region and to protect the chamber sidewalls 212 and the chamber interior wall 214 from the corrosive processing environment and to maintain an electrically isolated plasma environment. The liner 227 is supported in the chamber on a ledge 229 formed in the walls 212, 214 of each processing region 218, 220. A plurality of exhaust ports 231, or circumferential slots, are located about the periphery of the processing regions 218, 220 and disposed through each liner 227 to be in communication with the pumping channel 225 formed in the chamber walls and to achieve a desired pumping rate and uniformity. The number of ports and the height of the ports relative to the face plate of the gas distribution system are controlled to provide an optimal gas flow pattern over the wafer during processing.

A plasma is formed from one or more process gases or a gas mixture by applying an electric field from a power supply and heating the gas mixture, such as by the resistive heater element. The electric field is generated from coupling, such as inductively coupling or capacitively coupling, to the gas distribution system 208 with radio-frequency (RF) or microwave energy. In some cases, the gas distribution system 208 acts as an electrode. Film deposition takes place when the substrate is exposed to the plasma and the reactive gases provided therein. The substrate support and chamber walls are typically grounded. The power supply can supply either a single or mixed-frequency RF signal to the gas distribution system 208 to enhance the decomposition of any gases introduced into the chamber 106. When a single frequency RF signal is used, e.g., between about 350 kHz and about 60 MHz, a power of between about 1 and about 2,000 W can be applied to the gas distribution system 208.

A system controller controls the functions of various components such as the power supplies, lift motors, flow controllers for gas injection, vacuum pump, and other associated chamber and/or processing functions. The system controller executes system control software stored in a memory, which in the preferred embodiment is a hard disk drive, and can include analog and digital input/output boards, interface boards, and stepper motor controller boards. Optical and/or magnetic sensors are generally used to move and determine the position of movable mechanical assemblies. A similar system is disclosed in U.S. Pat. No. 5,855,681, entitled “Ultra High Throughput Wafer Vacuum Processing System,” issued to Maydan et al., filed on Nov. 18, 1996, also in U.S. Pat. No. 6,152,070, entitled “Tandem Process Chamber,” issued to Fairbairn et al., filed on Nov. 18, 1996. Both are assigned to Applied Materials, Inc., the assignee of the present invention. Another example of such a CVD process chamber is described in U.S. Pat. No. 5,000,113, entitled “Thermal CVD/PECVD Reactor and Use for Thermal Chemical Vapor Deposition of Silicon Dioxide and In-situ Multi-step Planarized Process,” issued to Wang et al., and in U.S. Pat. No. 6,355,560, entitled “Low Temperature Integrated Metallization Process and Apparatus,” issued to Mosely et al. and assigned to Applied Materials, Inc. The above CVD system description is mainly for illustrative purposes, and other plasma processing chambers may also be employed for practicing the embodiments described herein.

FIG. 3 is a process flow diagram 300 illustrating one embodiment of a method for cleaning a chamber according to embodiments described herein. At block 310, a chamber clean process is performed. The chamber clean process may be performed in the process chamber 106 by introducing cleaning gases, such as NF₃, CF₄, C₂F₆, or any other cleaning gases used in the industry, and striking a plasma, optionally including both an inductively and a capacitively coupled plasma, in the process chamber 106 according to methods known in the art to remove material deposited on the chamber walls and chamber components from a previous deposition process. At block 320, the gaseous reaction products formed between the cleaning gases and the deposition material and contaminants present within the chamber may be purged/evacuated out of the chamber.

At block 330, after the chamber clean process has been performed in the chamber 106, a combined oxidation and nitration chamber treatment may be performed in the process chamber 106. It is believed that the combined oxidation and nitration treatment for the chamber helps to recover the chamber clean etch rate as dopants such as boron react with oxygen and nitrogen atoms to form by-products which are easily removed from the chamber.

The combined oxidation and nitration chamber treatment may be performed by introducing nitration gases and oxidizing gases into the chamber either as a process gas mixture or separately. Exemplary oxidizing gases that may be used include oxygen (O₂), ozone (O₃), nitrous oxide (N₂O), carbon monoxide (CO), carbon dioxide (CO₂), water (H₂O), 2,3-butanedione, or combinations thereof. Exemplary nitration gases include ammonia (NH₃) and nitrogen (N₂). In one embodiment, the oxidizing gas comprises N₂O and the nitration gas comprises N₂.

The oxidizing gas may be introduced into the chamber at a flow rate of between about 7,000 sccm and about 14,000 sccm. The oxidizing gas may be introduced into the chamber at a flow rate of between about 8,000 sccm and about 10,000 sccm. The nitration gas may be introduced into the chamber at a flow rate of between about 3,000 sccm and about 10,000 sccm. The nitration gas may be introduced into the chamber at a flow rate of between about 4,000 sccm and about 6,000 sccm. In one embodiment, the oxidizing gas may be introduced into the chamber at a flow rate of about 9,000 sccm and the nitration gas may be introduced into the chamber at a flow rate of about 5,000 sccm.

Optionally, one or more carrier gases may be included with the gases used to perform the combined nitration and oxidation treatment. Exemplary carrier gases that may be used include argon, helium, and combinations thereof.

The combined oxidation and nitration chamber treatment is preferably a plasma enhanced processes. In a plasma enhanced process, a controlled plasma is typically formed adjacent the substrate support by RF energy applied to the gas distribution manifold of the deposition chamber using a RF power supply. Alternatively, RF power can be provided to the substrate support. The RF power to the deposition chamber may be cycled or pulsed. The power density of the plasma for a 200 or 300 mm substrate is between about 0.03 W/cm² and about 3.2 W/cm², which corresponds to a RF power level of about 10 W to about 1,000 W for a 200 mm substrate and about 20 W to about 2,250 W for a 300 mm substrate. In one embodiment, a high frequency power at 13.56 MHz is provided at a power level of about 700 watts during the combined nitration and oxidation treatment.

In any of the embodiments described herein, during the chamber treatment the chamber may be maintained at a temperature between about −20 degrees Celsius and about 600 degrees Celsius, for example, between about 400 degrees Celsius and about 550 degrees Celsius. The pressure during the chamber treatment may be between about 1 Torr and about 15 Torr (e.g., between about 1 Torr and about 10 Torr; between about 3 Torr and about 6 Torr). The distance between the pedestal and the showerhead is set to between about 200 mils to about 1,100 mils (e.g., between about 300 mils to about 1,100 mils).

Any by-products from the combined nitration and oxidation chamber treatment may then be removed from the chamber by performing the optional purge/evacuation process at block 340. Typical by-products formed after a boron doping process include, for example, boron nitride (BN) and boron trioxide (B₂O₃).

As shown in FIG. 3, at block 350, a first seasoning layer of a bi-layer seasoning layer is deposited. The first seasoning layer is a silicon oxide layer. The first seasoning layer may be deposited on the interior surfaces of the chamber including, for example, chamber components such as the face plate of the showerhead. In preparation for deposition of the first seasoning layer, the chamber may be evacuated (block 340), the distance between the pedestal and showerhead may be set to about 350 mils and the chamber may be maintained at a temperature from the previous process or heated to a temperature of about 550 degrees Celsius. A process gas that includes a silicon source gas, an oxidizing gas and an optional carrier gas is introduced into the chamber. Exemplary silicon source gases that may be used include TEOS, silane (SiH₄), and disilane (Si₂H₆). Exemplary oxidizing gases that may be used include oxygen (O₂), ozone (O₃), nitrous oxide (N₂O), carbon monoxide (CO), carbon dioxide (CO₂), water (H₂O), or combinations thereof. Exemplary carrier gases that may be used include argon, helium, nitrogen and combinations thereof.

In certain embodiments, the silicon source gas is TEOS, the oxidizing gas is nitrous oxide and the carrier gas is helium. TEOS may be introduced at a rate between about 500 mgm and about 5,000 mgm, for example, at a rate of about 4,000 mgm, vaporized and combined with a helium carrier gas flow introduced at 9,000 sccm before being introduced into the chamber. The helium carrier gas may be introduced into the chamber at a flow rate from about 5,000 sccm to about 15,000 sccm, for example, about 9,000 sccm. Nitrous oxide may be introduced into the chamber at a flow rate from about 5,000 sccm to about 20,000 sccm, for example about 16,000 sccm. A second source of helium, separate from the TEOS carrier gas, may be introduced into the chamber at a flow rate from about 100 sccm to about 15,000 sccm, for example, about 500 sccm. Pressure within the chamber may be set and maintained at from about 3 Torr to about 15 Torr (e.g., from about 3 Torr to about 10 Torr; about 4.6 Torr).

After the deposition conditions are stabilized, a plasma is formed from the process gas to deposit the silicon oxide seasoning layer. The plasma may be formed from mixed frequency RF power in which a high frequency RF component of 13.56 MHZ is powered at about 1,200 W and a low frequency RF component of 350 KHz is powered at about 330 W. For most applications, the plasma is maintained for about 15 to 60 seconds to deposit a seasoning layer of between about 1,500 Å to about 6,000 Å. The length of the first seasoning process depends in part on the amount of residue left in the chamber, which is in part dependent on the length of the clean and deposition processes.

In any of the embodiments described herein, during deposition of the first seasoning layer the chamber may be maintained at a temperature between about −20 degrees Celsius and about 600 degrees Celsius, preferably between about 400 degrees Celsius and about 550 degrees Celsius. The deposition pressure is typically between about 1 Torr and about 15 Torr (e.g., between about 1 Torr and about 10 Torr; between about 3 Torr and about 6 Torr). The distance between the pedestal and the showerhead is set to between about 200 mils to about 1,100 mils (e.g., between about 300 mils to about 1,100 mils).

The first seasoning layer may be deposited to have a thickness between about 1,000 Å and about 6,000 Å. The first seasoning layer may be deposited to have a thickness between about 2,000 Å and about 4,000 Å, for example, about 3,000 Å.

Any excess process gases and by-products from the deposition of the first seasoning layer may then be removed from the chamber by performing an optional purge/evacuation process between the processes of block 350 and block 360.

At block 360, a second seasoning layer of the bi-layer seasoning layer is deposited. The second seasoning layer is a silicon containing layer. The second seasoning layer may be a silicon oxynitride (SiON) layer or a silicon nitride (SiN) layer. In preparation for deposition of the second seasoning layer, the chamber may be evacuated, the distance between the pedestal and showerhead may be set to about 400 mils and the chamber may be maintained at a temperature from the previous process or heated to a temperature of 550 degrees Celsius. A process gas that includes a silicon source gas, an oxidizing gas and an optional carrier gas is introduced into the chamber. Exemplary silicon containing gases that may be used include silane (SiH₄), disilane (Si₂H₆), and TEOS. Exemplary oxidizing gases that may be used include oxygen (O₂), ozone (O₃), nitrous oxide (N₂O), carbon monoxide (CO), carbon dioxide (CO₂), water (H₂O), or combinations thereof. Exemplary carrier gases that may be used include argon, helium, nitrogen and combinations thereof.

In certain embodiments where the silicon containing seasoning layer is a SiON layer, the silicon source gas may be silane, the oxidizing gas may be nitrous oxide and the carrier gas may be nitrogen and/or helium. Silane may be introduced at a rate between about 100 sccm and about 1,000 sccm, for example, at a rate of about 460 sccm. Nitrous oxide may be introduced into the chamber at a flow rate from about 500 sccm to about 5,000 sccm, for example about 1,700 sccm. Nitrogen gas may be introduced into the chamber at a flow rate from about 5,000 sccm to about 15,000 sccm, for example, about 10,000 sccm. Optionally, helium may be used as a carrier gas and may be introduced into the chamber at a flow rate from about 500 sccm to about 15,000 sccm, for example, about 1,000 sccm. Pressure within the chamber may be set and maintained at from about 2 Torr to about 15 Torr (e.g., from about 2 Torr to about 10 Torr; about 3 Torr.

After the deposition conditions are stabilized, a plasma is formed from the process gas to deposit the SiON seasoning layer. The plasma may be formed from a high frequency RF component of 13.56 MHZ powered at about 500 W. For most applications, the plasma is maintained for about 15 to 60 seconds to deposit a seasoning layer of between about 1,500 Å to about 6,000 Å.

In certain embodiments where the silicon containing seasoning layer is a SiN layer, the silicon source gas may be silane and the nitrogen source gas may be nitrogen (N₂) or ammonia (NH₃). Silane may be introduced at a rate between about 100 sccm and about 1,000 sccm, for example, at a rate of about 460 sccm. Nitrogen may be introduced into the chamber at a flow rate from about 7,000 sccm to about 20,000 sccm, for example, about 15,000 sccm. Pressure within the chamber may be set and maintained at from about 2 Torr to about 15 Torr (e.g., from about 2 Torr to about 10 Torr; about 3 Torr).

After the deposition conditions are stabilized, a plasma is formed from the process gases to deposit the SiN seasoning layer. The plasma may be formed from a high frequency RF component of 13.56 MHZ powered at about 1,000 W. For most applications, the plasma is maintained for about 15 to 120 seconds to deposit a seasoning layer of between about 1,500 Å to about 6,000 Å.

In any of the embodiments described herein, during deposition of the second seasoning layer the chamber may be maintained at a temperature between about −20 degrees Celsius and about 600 degrees Celsius, preferably between about 400 degrees Celsius and about 550 degrees Celsius. The deposition pressure is typically between about 1 Torr and about 15 Torr (e.g., between about 1 Torr and about 10 Torr; between about 2.5 Torr and about 7 Torr). The distance between the pedestal and showerhead is set to between about 200 mils to about 1,100 mils (e.g., between about 300 mils to about 1,100 mils).

The second seasoning layer may be deposited to have a thickness between about 1,000 Å and about 6,000 Å. The second seasoning layer may be deposited to have a thickness between about 2,000 Å and about 4,000 Å, for example, about 3,000 Å.

Any excess process gases and by-products from the deposition of the second seasoning layer may then be removed from the chamber by performing an optional purge-evacuation process after the process of block 360 at block 370.

After block 370 additional substrate processing may be performed in the processing chamber.

FIG. 4 is a graph 400 illustrating the clean etch rate reduction for various processes according to embodiments described herein. The y-axis represents the deterioration or reduction in the clean etch rate (micrometers/minute). The x-axis represents the type of process performed. To determine the clean etch rate reduction depicted in FIG. 4, the processing chamber was cleaned with an NF₃ RPS clean as described herein. The clean etch rate was measured after the clean process and prior to deposition of boron doped a-Si on a lot of 25 wafers. Then the clean etch rate was measured after deposition of boron doped a-Si on a lot of 25 wafers. The pre-deposition clean etch rate and the post-deposition clean etch rate are compared and the difference between the post and pre provides the drop or difference in the clean etch rate. The following processes were then performed. The process labeled “BKM” (410) was performed with a RPS NF₃ chamber clean only without a combined oxidation and nitration treatment, B₂H₆ stabilization or deposition of a bi-layer seasoning layers. As shown in graph 400, for the process labeled “BKM”, the clean etch rate deteriorated at a rate of about 0.7 micrometers/minute. The process labeled “N₂O+N₂ trt” (420) was performed with a RPS NF₃ chamber clean followed by a combined nitration and oxidation process as described herein. As shown in graph 400, for the process labeled N₂O+N₂ treatment, the clean etch rate deteriorated at a rate of about 0.45 micrometers/minute. The process labeled “B2H6-no stab” (430) involved the elimination of a stabilization process where additional B₂H₆ was flown into the chamber to stabilize the gases present prior to introduction of plasma. This diborane stabilization process was eliminated because the stabilization process typically resulted in the formation of additional boron. As shown in graph 400, for the process labeled “B2H6-no stab”, the clean etch rate deteriorated at a rate of about 0.55 micrometers/minute. The process labeled “bilayer season” (440) was performed with a RPS NF₃ chamber clean followed by deposition of a silicon oxide/silicon oxynitride seasoning bi-layer as described herein. As shown in graph 400, for the process labeled bilayer season, the clean etch rate deteriorated at a rate of less than about 0.05 micrometers/minute.

FIG. 5 is a graph 500 illustrating the effect of single layer seasoning layers and seasoning bi-layers formed according to embodiments described on the number of particles (>0.13 micrometers) generated. The y-axis represents number of particles generated (>0.13 micrometers). The x-axis represents the type of seasoning layer used. The number of particles added for each single layer seasoning layer and seasoning bi-layer are represented by bars 510-570. After deposition of the seasoning layers, stack of films with alternating oxide (250 Å) and amorphous silicon (350 Å) for 36 times were deposited to a thickness of about 2.2 micrometers and particulates were measured. TEOS indicates that the seasoning layer was a silicon oxide layer deposited using TEOS. Particles added for single layer seasoning layers are depicted as bar 510 (4,000 Å SiON seasoning layer) and bar 570 (4,000 Å silicon oxide seasoning layer). Although the 4,000 Å silicon oxide seasoning layer represented by bar 570 exhibited the best particle performance the TEOS season by itself showed degradation of the clean etch rate. The 4,000 Å SiON seasoning layer represented by bar 510 prevented clean etch rate degradation but exhibited poor particle performance. As shown in Table I and FIG. 5, the 3,000 Å TEOS oxide/3,000 Å SiON bi-layer represented by bar 540 exhibited the best combination of particle performance while maintaining the clean etch rate.

TABLE I

| | Clean Etch Rate (micrometers/minute) | |
|---|---|---|
| Condition | Side 1 | Side 2 |
| Prior to OP lot | 3.35 | 2.92 |
| After 1 lot 24.5X OP stack | 3.33 | 2.88 |

While the foregoing is directed to embodiments of the present invention, other and further embodiments of the invention may be devised without departing from the basic scope thereof, and the scope thereof is determined by the claims that follow.

1. A method for reducing sorbable contaminants in a substrate processing chamber prior to substrate processing, comprising:
cleaning a processing chamber with a plasma comprising a cleaning gas;
exposing at least a portion of the interior surfaces of the processing chamber to an oxidation gas and a nitration gas in the presence of a plasma; and
depositing a bi-layer seasoning layer on the interior surfaces of the processing chamber.

2. The method of claim 1, wherein depositing the bi-layer seasoning layer comprises:
depositing a silicon oxide layer on the interior surfaces of the processing chamber; and
depositing a silicon containing layer on the silicon oxide layer.

3. The method of claim 2, wherein the silicon containing layer is one of a silicon nitride (SiN) layer or silicon oxynitride (SiON) layer.

4. The method of claim 1, wherein the cleaning gas is selected from a group consisting of: NF₃, CF₄, and C₂F₆.

5. The method of claim 2, wherein the silicon oxide layer is formed from a reactive gas comprising: TEOS, nitrous oxide and helium.

6. The method of claim 3, wherein the silicon oxynitride layer is formed from a reactive gas comprising: silane, nitrous oxide, and nitrogen.

7. The method of claim 3, wherein the silicon nitride layer is formed from a reactive gas comprising silane and nitrous oxide.

8. The method of claim 1, wherein the sorbable contaminants comprise at least one of: boron and fluorine.

9. The method of claim 1, wherein the plasma comprising a cleaning gas is formed by a remote plasma source (RPS).

10. The method of claim 1, wherein the plasma for the oxidation gas and the nitration gas is formed by applying RF energy to a showerhead of the processing chamber using an RF power supply.

11. The method of claim 1, wherein the interior surfaces of the processing chamber include chamber components.

12. The method of claim 1, further comprising:
purging gaseous reaction products formed between the cleaning gas and contaminants present within the processing chamber prior to exposing at least a portion of the interior surfaces of the processing chamber to an oxidation gas and a nitration gas in the presence of a plasma.

13. The method of claim 1, further comprising:
purging by-products from the combined nitration and oxidation chamber prior to depositing a bi-layer seasoning layer on the interior surfaces of the processing chamber.

14. The method of claim 2, wherein the bi-layer seasoning layer comprises:
a first seasoning layer having a thickness from between about 1,000 Å and about 6,000 Å; and
a second seasoning layer having a thickness from between about 2,000 Å and about 4,000 Å.

15. The method of claim 14, wherein the chamber is maintained at a temperature between about 400 degrees Celsius and about 550 degrees Celsius and the deposition pressure is between about 1 Torr and about 10 Torr during deposition of the first seasoning layer.

16. A method for reducing sorbable contaminants in a processing chamber, comprising:
cleaning a processing chamber having a substrate support and a showerhead disposed therein with a plasma comprising an NF₃ cleaning gas, wherein the plasma is formed by a remote plasma source;
exposing at least a portion of the interior surfaces of the processing chamber to an oxidation gas and a nitration gas in the presence of a plasma; and
depositing a bi-layer seasoning layer on the interior surfaces of the processing chamber, wherein the bi-layer seasoning layer comprises:
a silicon oxide layer formed on the interior surfaces of the processing chamber; and
a silicon oxynitride layer formed on the silicon oxide layer.

17. The method of claim 16, wherein the silicon oxide layer is formed from a reactive gas comprising: TEOS, nitrous oxide and helium.

18. The method of claim 17, wherein the silicon oxynitride layer is formed from a reactive gas comprising: silane, nitrous oxide, and nitrogen.

19. The method of claim 16, wherein the plasma for the oxidation gas and the nitration gas is formed by applying RF energy to the showerhead.

20. The method of claim 16, wherein silicon oxide layer has a thickness from between about 1,000 Å and about 6,000 Å and the silicon oxynitride layer has a thickness from between about 2,000 Å and about 4,000 Å.
